(19) United States
(12) Patent Application Publication
(10) Pub. No.: US 2024/0154445 A1
(43) Pub. Date: May 9, 2024

(54) INTELLIGENT BMS CHARGE CONTROL

(71) Applicant: Nova Semiconductor Inc., San Jose, CA (US)

(72) Inventors: Ahmad Rick Ashrafzadeh, Morgan Hill, CA (US); Adam John Whitworth, Los Gatos, CA (US)

(21) Appl. No.: 18/502,917

(22) Filed: Nov. 6, 2023

Related U.S. Application Data
(60) Provisional application No. 63/423,316, filed on Nov. 7, 2022.

(51) Int. Cl. H02J 7/00; G01R 31/389; G01R 31/392; H01M 10/42

(52) U.S. Cl. CPC H02J 7/00714; G01R 31/389; G01R 31/392; H01M 10/425; H02J 7/007182; H02J 7/007192; H01M 2010/4271; H02J 2207/20

(57) ABSTRACT

A method for controlling a charge to a battery pack via a battery management system (BMS) integrated circuit (IC) includes monitoring one or more parameters associated with the battery pack. The method also includes monitoring a charge output from a direct current (DC)-DC converter to the battery pack. The method further includes adjusting feedback to the DC-DC converter in accordance with monitoring the one or more parameters and monitoring the charge output, the feedback being a local feedback to the DC-DC converter or a reference input to the DC-DC converter.

### CROSS-REFERENCE TO RELATED APPLICATION

The present application claims the benefit of U.S. Provisional Patent Application No. 63/423,316, filed on Nov. 7, 2022, and titled “INTELLIGENT BMS CHARGE CONTROL,” the disclosure of which is expressly incorporated by reference in its entirety.

### FIELD OF THE DISCLOSURE

This invention relates to battery charging, more specifically battery charging and battery management system (BMS) integrated circuits (ICs).

### BACKGROUND

Conventional battery chargers reside on a system printed circuit board. These conventional chargers typically provide a correct amount of the charge, and implement a charge profile to safely charge a battery pack. Some conventional chargers include fully autonomous integrated circuits (ICs). These types of chargers may be referred to as IC chargers or charging ICs (hereinafter used interchangeably). An IC charger manages the charging process for rechargeable batteries, such as those in smartphones or electric vehicles. Its design encompasses basic components found in a simple converter, such as a direct current (DC)-DC converter, but also integrates advanced circuitry for monitoring and regulating the charge. In some cases, an alternative current (AC)-DC converter may replace the DC-DC converter. This ensures batteries are charged efficiently, safeguarding against potential hazards like overcharging or overheating. Because IC chargers include advanced circuitry for monitoring and regulating the charge, an IC charger may be more complex and costly in comparison to the DC-DC converter.

A battery management system (BMS) IC is a component in managing rechargeable battery systems commonly found in electric vehicles, consumer electronics, and renewable energy storage. The BMS IC may control various functions of a battery pack. A primary function of a BMS IC is to monitor and control the battery's charging and discharging processes, ensuring the cells remain within their safe operational limits. Components of a BMS include, but are not limited to, voltage monitoring systems for each cell, temperature sensors, a current sensor, a central microcontroller unit (MCU), protection circuitry, and communication interfaces, such as controller area network (CAN), I2C, and universal asynchronous receiver-transmitter (UART). These components work together to perform various functions, including cell balancing, state of charge (SoC) calculation, state of health (SoH) estimation, fault detection, and data logging. The importance of a BMS cannot be overstated, as it ensures the safety, reliability, and longevity of battery systems by preventing hazardous situations like overcharging or deep discharging, which could lead to battery failures or fires. By optimizing battery operations, a BMS also extends the battery's overall lifespan.

### SUMMARY

In one aspect of the present disclosure, a method for controlling a charge to a battery pack includes monitoring one or more parameters associated with the battery pack. The method still further includes monitoring a charge output from a direct current (DC)-DC converter to the battery pack. The method also includes adjusting feedback to the DC-DC converter in accordance with monitoring the one or more parameters and monitoring the charge output, the feedback may be a local feedback to the DC-DC converter or a reference input to the DC-DC converter.

Another aspect of the present disclosure is directed to an apparatus including means for monitoring one or more parameters associated with the battery pack. The apparatus further includes means for monitoring a charge output from a direct current (DC)-DC converter to the battery pack. The apparatus further includes means for adjusting feedback to the DC-DC converter in accordance with monitoring the one or more parameters and monitoring the charge output, the feedback may be a local feedback to the DC-DC converter or a reference input to the DC-DC converter.

In another aspect of the present disclosure, a non-transitory computer-readable medium with non-transitory program code recorded thereon is disclosed. The program code is executed by a processor and includes program code to monitor one or more parameters associated with the battery pack. The program code still further includes program code to monitor a charge output from a direct current (DC)-DC converter to the battery pack. The program code also includes program code to adjust feedback to the DC-DC converter in accordance with monitoring the one or more parameters and monitoring the charge output, the feedback may be a local feedback to the DC-DC converter or a reference input to the DC-DC converter.

Another aspect of the present disclosure is directed to an apparatus having at least one processor and at least one memory coupled with the at least one processor and storing instructions operable, when executed by the processor, to cause the apparatus to monitor one or more parameters associated with the battery pack. Execution of the instructions further cause the apparatus to monitor a charge output from a direct current (DC)-DC converter to the battery pack. Execution of the instructions also cause the apparatus to adjust feedback to the DC-DC converter in accordance with monitoring the one or more parameters and monitoring the charge output, the feedback may be a local feedback to the DC-DC converter or a reference input to the DC-DC converter.

In some aspects, a charging system is presented. The charging system includes a direct current (DC)-DC converter, a battery pack, and a battery management system (BMS) integrated circuit (IC). The BMS IC may monitor one or more parameters associated with the battery pack. The BMS IC may also monitor a charge output from the DC-DC converter to the battery pack. The BMS IC may further adjust feedback to the DC-DC converter in accordance with monitoring the one or more parameters and monitoring the charge output, the feedback being a local feedback to the DC-DC converter or a reference input to the DC-DC converter.

Aspects generally include a method, apparatus, system, computer program product, non-transitory computer-readable medium, user equipment, base station, wireless communication device, and processing system as substantially described with reference to and as illustrated by the accompanying drawings and specification.

The foregoing has outlined rather broadly the features and technical advantages of examples according to the disclosure in order that the detailed description that follows may be better understood. Additional features and advantages will be described. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

So that features of the present disclosure can be understood in detail, a particular description may be had by reference to aspects, some of which are illustrated in the appended drawings. It is to be noted, however, that the appended drawings illustrate only certain aspects of this disclosure and are therefore not to be considered limiting of its scope, for the description may admit to other equally effective aspects. The same reference numbers in different drawings may identify the same or similar elements.

FIG. 1 is a block diagram illustrating an example of a conventional charger.

FIG. 2 is a diagram illustrating an example of a conventional charge profile.

FIG. 3 is a block diagram illustrating an example of a smart system controller.

FIGS. 4, 5, 6, 7, 8, and 9 are block diagrams illustrating examples of a battery management system (BMS) integrated circuit (IC), in accordance with various aspects of the present disclosure.

FIG. 10 is a flow diagram illustrating an example process for controlling an output of a direct current (DC)-DC converter, in accordance with various aspects of the present disclosure.

### DETAILED DESCRIPTION

Various aspects of the disclosure are described more fully below with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings, one skilled in the art should appreciate that the scope of the disclosure is intended to cover any aspect of the disclosure, whether implemented independently of or combined with any other aspect of the disclosure. For example, an apparatus may be implemented or a method may be practiced using any number of the aspects set forth. In addition, the scope of the disclosure is intended to cover such an apparatus or method, which is practiced using other structure, functionality, or structure and functionality in addition to or other than the various aspects of the disclosure set forth. It should be understood that any aspect of the disclosure disclosed may be embodied by one or more elements of a claim.

Several aspects of battery and charging systems will now be presented with reference to various apparatuses and techniques. These apparatuses and techniques will be described in the following detailed description and illustrated in the accompanying drawings by various blocks, modules, components, circuits, steps, processes, algorithms, and/or the like (collectively referred to as “elements”). These elements may be implemented using hardware, software, or combinations thereof. Whether such elements are implemented as hardware or software depends upon the particular application and design constraints imposed on the overall system.

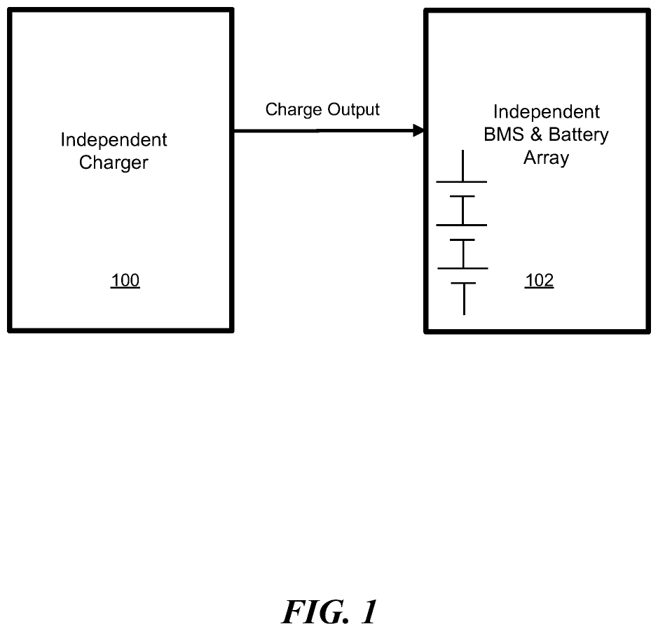

FIG. 1 is a block diagram illustrating an example of a conventional charger 100. In the example of FIG. 1, the charger 100 and a BMS IC 102 are independent. The charger 100 provides a charge current based on one or more of a predetermined profile, a battery pack overall voltage, a temperature of an environment, or one or more individual cell temperatures.

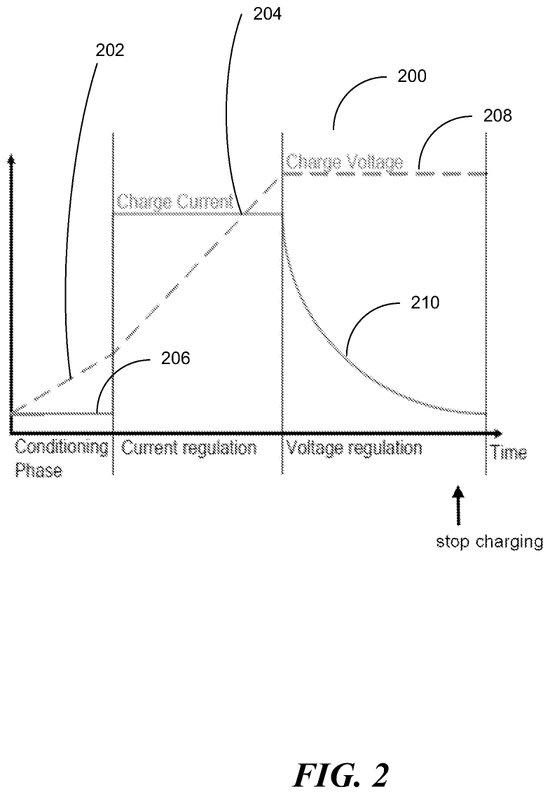

FIG. 2 is a diagram illustrating an example of a conventional charge profile 200. The charge profile 200 may be associated with a lithium-ion (Li-Ion) charger. As shown in the example of FIG. 2, a first phase (conditioning phase) of the charge profile 200 uses a low current 206 to bring up a battery voltage 202 to a threshold level. Then, a high charge current 204 can be applied at a current regulation phase, where the current 204 is fixed current and applied to charge the battery such that its voltage reaches a final target voltage. The third phase is a voltage regulation phase, where a fixed voltage 208 is applied to the battery, while monitoring the current 210. When the current falls below a threshold, the charge is terminated, and the battery is deemed full.

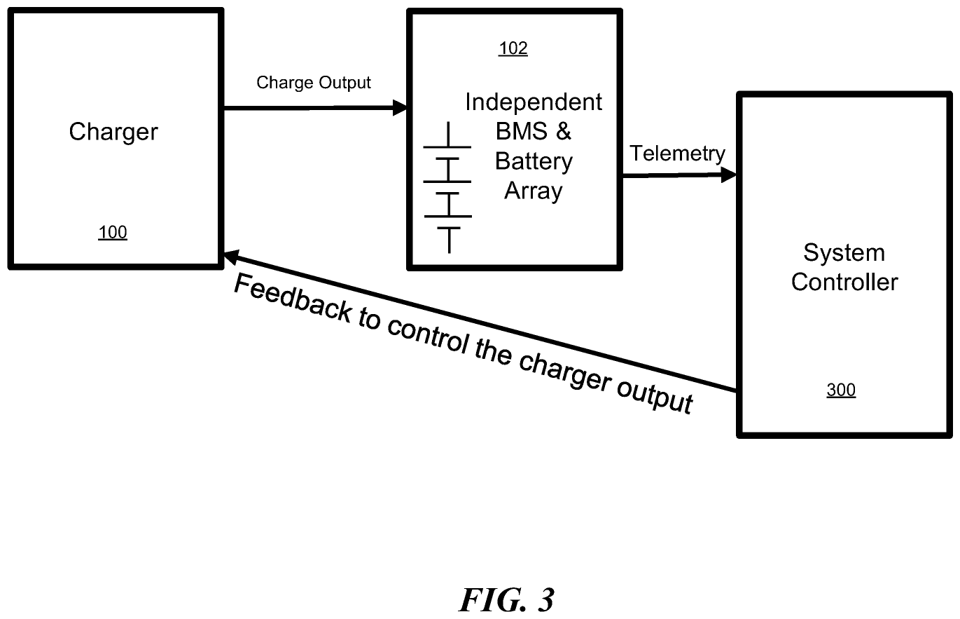

FIG. 3 is a block diagram illustrating an example of a system controller 300. In the example of FIG. 3, the system controller 300 reads telemetry provided by the BMS IC 102, and uses this information to tailor a charge profile at the charger 100. The system controller 300 may also be referred to as a smart system controller 300. The charge profile may be updated based on specific commands (e.g., feedback) sent from the system controller 300 the charger to provide a different output current or voltage for charging profile optimization.

Various aspects of the present disclosure are directed to a new battery charging scheme. This new battery charging scheme may provide a new class of chargers, where the intelligence for charge control resides in a fuel gauge integrated circuit (IC), which may be referred to as a battery management system (BMS) IC. The BMS IC is distinguishable from fully autonomous charging ICs. In some examples, the BMS IC uses and controls a DC-DC converter, in place of a full-featured IC charger, to create a low-cost and accurate battery charging system to improve a charge profile while reducing the cost associated with a charger. The terms voltage regulator and DC-DC or AC-DC converters are used interchangeably.

A DC-DC converter is an electronic device that receives a direct current (DC) input voltage and outputs a different DC voltage. In some examples, the DC-DC converter may change a level of power or voltage coming from a source to fit the needs of a device or system. For example, most electronic devices require specific voltage levels to operate correctly. For example, a device might run on 5 volts, but the available power source provides 12 volts. A DC-DC converter can step down this voltage to the required 5 volts, ensuring the device functions without getting damaged. Accordingly, a DC-DC converter acts much like an adjustable tap in a water system, modulating the flow or voltage level of electricity to cater to diverse needs. Its chief role is to transform one DC voltage level to another, either amplifying (stepping up) or reducing (stepping down) the voltage. The DC-DC converter may be used to ensure each component receives its requisite voltage. This is achieved through a combination of inductors, capacitors, and switches, which, by swiftly toggling on and off, control energy storage and release to produce the desired voltage.

As discussed, conventional charging systems are predominantly located on the system's printed circuit board. This stands in contrast to BMS ICs, which are more commonly integrated directly within a battery pack or associated with the battery pack. The battery pack refers to a battery of a device. The battery pack may include one or more batteries. Each battery may include one or more cells. BMS ICs may be specified for various functions, such as, but not limited to, protecting the battery pack against overcharging or discharging, gauging charge to measure the battery's state of charge, and cell balancing to ensure uniform charge levels across all cells. In most cases, conventional chargers are used to provide a consistent charge to the battery pack. However, many conventional chargers also include a monitoring mechanism to assess the battery's needs and adjust the charging process accordingly, ensuring the battery is charged in the safest and most efficient manner possible. Notwithstanding, having a distinct separation between the charging and monitoring functions in two separate systems can lead to inefficiencies and is not the most optimal approach for battery management.

In most cases, the BMS IC is positioned in close proximity to the battery pack. For example, the BMS IC and the battery pack may be in the same housing structure. This positioning allows the BMS IC to gather comprehensive data (e.g., one or more parameters) about the state of various parameters associated with the battery pack. The one or more parameters may include, but are not limited to, the health or aging status of the battery pack, ambient temperature, temperature of the battery pack and/or individual cells, internal resistance, individual cell voltage levels, and the flow of currents entering and exiting the battery pack. The one or more parameters may also be referred to as telemetry of the battery pack. Given this in-depth knowledge, the BMS IC is best equipped to make informed decisions about the charging profile. In some examples, the BMS IC can adapt to evolving battery conditions and external environmental factors while ensuring the most suitable charging profile is applied throughout a lifecycle of the battery pack.

Prioritizing accuracy, the BMS IC can be engineered to control a DC-DC converter. This DC-DC converter may be devoid of intricate charging functionalities and the precision typically associated with a charging IC, which lowers the overarching system expenses. In some examples, the BMS IC may turn a simple and low-cost DC-DC converter into a high-performance charger, by controlling the DC-DC converter through feedback and/or a reference input. In some examples, by regulating the feedback and/or reference input, the BMS IC may dictate the output of the DC-DC converter. For example, by using telemetry data at its disposal, the BMS IC can dictate a charging current and profile, such that the charge and profile align with the specifications of the battery pack.

A charge profile provides a structured approach to battery charging, ensuring safety, longevity, and maximum energy storage. The process may begin with a pre-qualification or trickle charge phase. Here, the battery pack may receive a minimal current until it reaches a safe voltage level, preparing the battery pack for the more intense charging phases. This initial stage seamlessly transitions into the constant current phase, where the battery pack absorbs the majority of its charge. During this stage, a steady high current is supplied, causing the battery pack's voltage to rise incrementally until a predetermined level is achieved.

Once this threshold is reached, the charger switches to the constant voltage phase. Instead of focusing on constant current, the emphasis now shifts to maintaining a stable voltage. As the battery pack approaches full capacity, the current naturally diminishes. When it drops to a particularly low point, it indicates near full charge, concluding this phase. Some advanced chargers incorporate a battery pack analysis or top-off charging step, offering intermittent small charges to counteract any self-discharge and ensure the battery remains at peak capacity.

For battery packs that stay connected post-charging, a maintenance or float charge phase comes into play. This phase provides a minimal current, just enough to offset the battery's self-discharge, ensuring the battery remains fully charged without degradation. In essence, a charge profile acts as a charger's roadmap, guiding it in delivering an optimal charge tailored to specific battery requirements, whether it is Li-ion, NIMH, or Lead-Acid. An optimal charge may refer to charging the battery pack as fast as possible while satisfying safety conditions.

Achieving an optimum charge for a battery pack is a tradeoff between efficiency and safety. Charging at high speeds can produce significant heat, potentially harming the battery and shortening its lifespan. Therefore, it may be desirable to satisfy safety criteria while satisfying speed specifications. In some examples, the BMS IC may continuously monitor one or more parameters, such as battery temperature, voltage, and/or current. If any irregularities arise, the BMS IC can adjust the charging rate or even halt the process altogether to prevent potential hazards. Beyond safety, the longevity of the battery is considered. Every battery pack has a finite number of charge cycles, and preserving charges may increase the battery pack's longevity. To strike this balance, the BMS IC may charge the battery pack up to a certain battery percentage, followed by a more controlled, slower charge as it approaches full capacity. This method aims to combine quick power-ups and battery health maintenance. In summary, the optimal charge is an example of maximizing charging speed while satisfying safety criteria.

Conventional systems may read telemetry information from the BMS IC, and use this information to update a charge current and profile at the charging IC. Still, this capability is limited and requires system intervention. Various aspects of the present disclosure provide more flexibility and autonomous control of the charge profile. In some examples, the BMS IC may control a charge function, which may vary depending on one or more inputs from the battery pack. The one or more inputs may include a health and/or state of one or more cells, environment conditions (e.g., a current temperature), a history of events, and/or current system consumption.

Voltage or current regulators generally have to implement a high speed closed loop control to regulate the output voltage and current, respectively. In most cases, chargers implement one of these two modes of operations (e.g., constant current or constant voltage) at any given time. As the name implies, in the constant current mode, the regulator controls the output current, and for the purpose of closing the regulation loop, the output voltage is ignored. The constant voltage is designed to provide a fixed output voltage, and the amount of output current is ignored, at least for closing the control loop. In Lithium-Ion battery charging, assuming the battery is not depleted below a safety point, the charger starts off by providing a constant current to the battery pack, until a target voltage is reached. Once at this target voltage, the charger will provide a constant voltage, until the output current is at a predetermined minimum level, which will trigger a charge termination.

These two modes of operation are some of the main functions of a charger, however, a full-feature charger will have to provide other functions, such as safety limits, charge time limits, programmability, and communication with the system. All of these functions specify a threshold level of accuracy to keep the battery pack safe and avoid damaging the batteries (e.g., preventing fire). These intricacies and the requisite accuracy differentiate chargers from voltage regulators in terms of complexity and cost. That is, chargers are more costly than voltage regulators.

Various aspects of the present disclosure remove the discussed complexities and the need for high accuracy, thereby simplifying voltage and/or charge regulating by controlling an output of a DC-DC converter to follow a charge profile throughout a charge cycle. The output may be controlled by adjusting feedback to the DC-DC converter and/or a reference input to the DC-DC converter. Because the BMS IC is monitoring the battery pack, and has the telemetry information, in addition to a complex state machine or, in most cases, a processor, the BMS IC is fully capable of determining the steps for providing a charge current to charge the batteries. The BMS IC may monitor the battery pack and use telemetry to determine a charge profile at any given time. The charge profile may be an optimal charge profile. This is in contrast to charging ICs, which are fixed in their function and only determine a charging mode based on predefined parameters. In some conventional systems, a system processor may intervene and use the telemetry obtained from the BMS IC to make adjustments to the charger. However, this process does not simplify the charger functionality, and the adjustments are often incremental. For example, such adjustments may be “one size fits all” adjustments associated with a preset profile. These adjustments are not adapted to a current condition of a battery pack. For example, these adjustments do not consider an age of the battery pack and/or a current temperature. In contrast, the continuous control provided by the BMS IC adapts a charge profile based on various conditions, including battery specific conditions (e.g., age) and/or environmental conditions (e.g., temperature).

Various processes may control an output of a DC-DC converter. The DC-DC converter is an example of a voltage regulator. In some examples, a reference voltage used by the DC-DC converter may be controlled. The DC-DC converter may match feedback to its reference voltage. Therefore, adjusting the reference voltage may adjust the output voltage from the DC-DC converter. Additionally, or alternatively, in some examples, the feedback signal may be adjusted. Feedback may be associated with all or a portion of the output voltage from the DC-DC converter. The DC-DC converter may adjust the feedback to be the same as an input reference signal. The feedback may be adjusted (e.g., increased or decreased) by adjusting the output voltage from the DC-DC converter. Therefore, by controlling the feedback to the DC-DC converter, a device, such as a the BMS IC, may override a conventional control loop and adjust an output voltage from the DC-DC converter to a desired direction (e.g., increase or decrease the output voltage). Modifying the feedback may adjust the output without the DC-DC converter sensing this change.

In some examples, the feedback (e.g., control processes) may operate in an analog domain or digital domain. The digital feedback may improve noise resistance and robustness. In some examples, serial communication may drive a DAC (digital-to-analog converter). The DAC output may be used to adjust the feedback or the reference input.

Additionally, or alternatively, digital communication can use programmable frequencies, which can be translated into voltages or currents to facilitate the required adjustments. In some examples, a switched-capacitor engine may facilitate changing a frequency to an analog voltage or current. Combining frequency with a switched capacitor offers a variable resistance or current, serving as a cost-effective and noise-immune solution.

In some examples, various optimizations and adaptions may be possible in accordance with the BMS IC taking control of the charge current and profile. As previously discussed, in addition to maintaining safety, the goal of most chargers is to charge the batteries as fast as possible. Still, there are various limitations in conventional fast charging, these include, but are not limited to, available power, maximum allowed charge current (based on the manufacturer specifications), and/or battery pack temperature. One of the main factors in a battery's health degradation is high temperature. There is a direct relation between charge current and heat generation in batteries. Because the ambient temperature is not fixed, and because battery impedance changes over its life, fixing the charge current may result in reducing a charging speed. In such cases, a safe current is provided in all conditions. Alternatively, if the charge speed is increased, the battery pack may overheat beyond what is healthy and/or desired. Thus, by adjusting the charge current based on real-time data (e.g., individual battery pack temperature), battery packs can be charged swiftly and safely.

As mentioned above, the impedance of the batteries also increases over time. Because heat generation is a direct function of the impedance, a fixed charge current means either undercutting the charge speed to be safe, or exceeding the safe current when the impedance has increased. In accordance with various aspects of the present disclosure, the BMS IC may monitor the impedance of every battery cell, thus, the BMS IC may adjust an output of the DC-DC converter to prevent overheating the cell. That is, as a battery pack is charged, the cell voltage needs to be kept under control, meaning a maximum cell voltage threshold should not be exceeded. If one or more cells have a higher impedance, compared to the others, these battery cell voltages rise faster than others. In conventional systems, a protection function may prematurely stop the charge, which will result in undercharging the pack. In various aspects of the present disclosure, because the BMS IC has the knowledge of individual cell impedances, as well as the individual cell voltages, the BMS IC can reduce the charging current to allow a more effective charge, where the pack reaches a higher level of charge compared to conventional charge methods. Effectively, this will increase the useful life of a battery pack.

In some cases, a wall adapter may be used as a primary power source to both charge the battery and run the system. In such cases, the wall adapter not only powers the device but simultaneously charges its battery. Given this dual responsibility, it may be desirable to modulate the charging current to ensure the system has adequate power to function seamlessly. In this context, the BMS IC may measure the system's power consumption, and by understanding the constraints of the power source through set parameters, the BMS IC may dynamically determine the appropriate charging current for the battery pack. This process may be autonomously managed by the BMS IC, which continuously monitors power usage to adjust the charging current. Using data on the energy supplied to the battery, the BMS IC can fine-tune both the charging duration and current to ensure the battery reaches its full capacity efficiently.

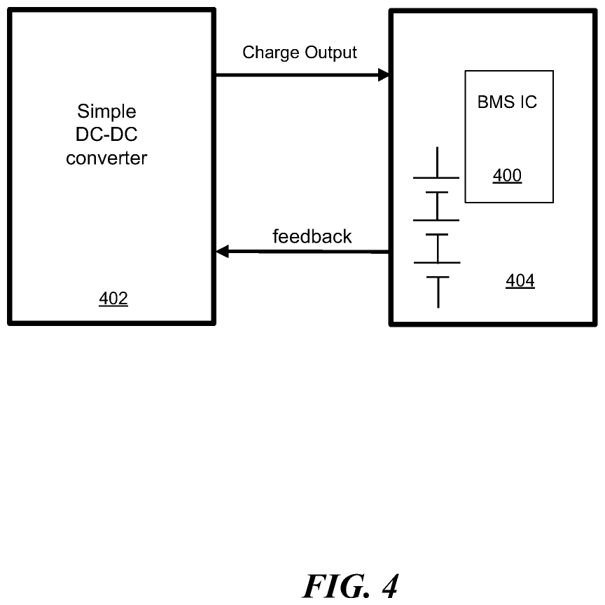

FIG. 4 is a block diagram illustrating an example of a BMS IC 400 in accordance with various aspects of the present disclosure. In the example of FIG. 4, the BMS IC 400 is integrated with a battery pack 404. As shown in the example of FIG. 4, the BMS IC 400 provides feedback (e.g., feedback control) to a DC-DC converter 402 (e.g., a regulator) to directly control the charge output of the DC-DC converter 402. In some examples, the feedback may be continuous. Additionally, in response to receiving the feedback, the DC-DC converter 402 may provide a charge corresponding to a charge profile. The charge profile may be based on battery pack telemetry available to the BMS IC 400. This DC-DC converter 402 may be unaware of the charge profile, such that the DC-DC converter 402 is a simple device that has a lower cost in comparison to complex chargers.

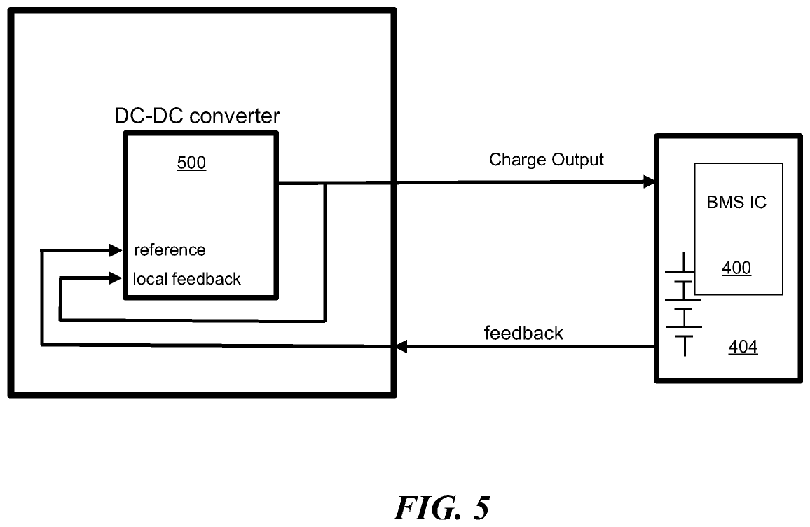

FIG. 5 is a block diagram illustrating another example of a BMS IC 400, in accordance with various aspects of the present disclosure. In the example of FIG. 5, the feedback from the BMS IC 400 is used as a reference of a DC-DC converter 500 to control the charge output (e.g., charge or voltage) of the DC-DC converter 500. The output of the DC-DC converter 500 may be received at the battery pack 404 and BMS IC 400. Additionally, the output of the DC-DC converter 500 may be received as local feedback. By adjusting a value of the reference, the BMS IC 400 may cause the DC-DC converter 500 to adjust the output. In some examples, the feedback may be continuous.

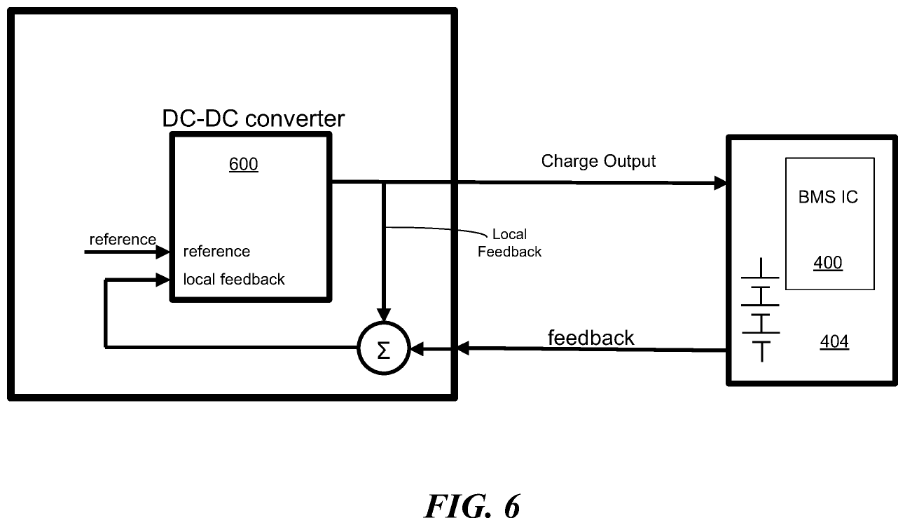

FIG. 6 is a block diagram illustrating another example of a BMS IC 400, in accordance with various aspects of the present disclosure. In the example of FIG. 6, feedback from the BMS IC 400 is added to the local feedback, via an adding function E, to control the output of the DC-DC converter 600. In some examples, the feedback from the BMS IC 400 may be modified to appear lower or higher than a nominal feedback. A perceived higher voltage lowers the charge output of the DC-DC converter 600. The perceived lowered feedback causes the controller DC-DC converter 600 to increase the output.

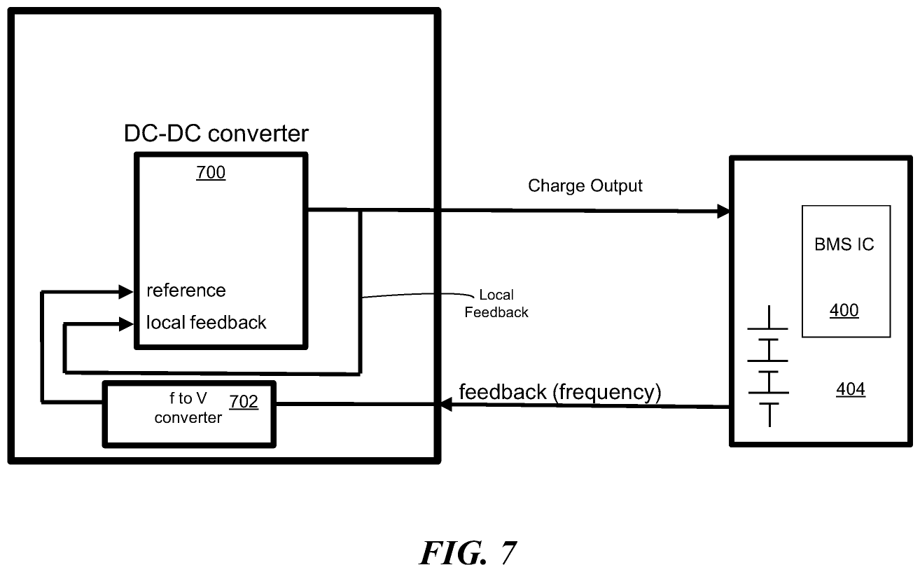

FIG. 7 is a block diagram illustrating another example of a BMS IC 400, in accordance with various aspects of the present disclosure. In the example of FIG. 7, instead of sending sensitive analog voltage as feedback, the BMS IC 400 sends variable frequency feedback to control the DC-DC converter 700. This variable frequency is converted to a variable voltage through a frequency to voltage (f to V) converter 702, where the output of the frequency to voltage converter 702 can be used as an input to the reference input. Sending the variable frequency feedback provides a high degree of immunity compared to sending an analog voltage, as the reference input is a sensitive node and should have a noise free and clean signal.

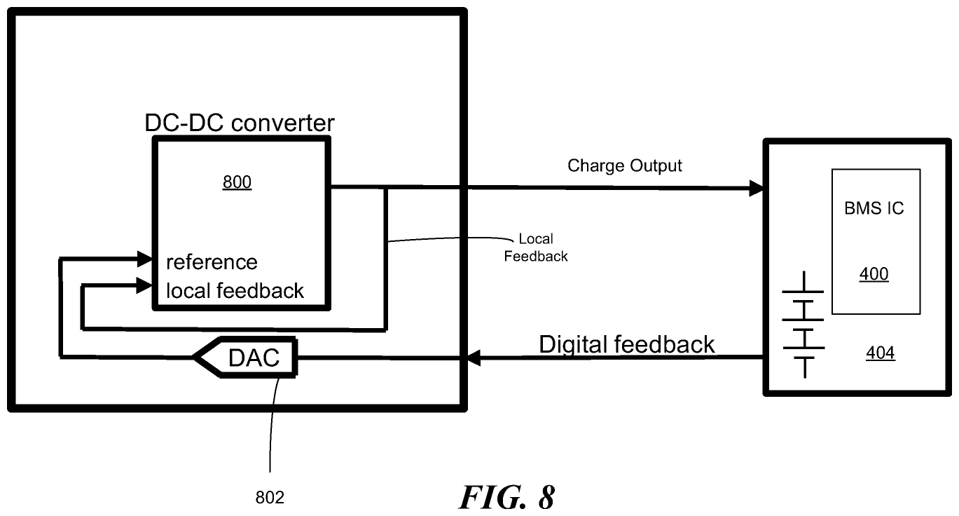

FIG. 8 is a block diagram illustrating another example of a BMS IC 400, in accordance with various aspects of the present disclosure. In the example of FIG. 8, a digital-to-analog converter (DAC) 802 converts digital feedback from the BMS IC 400 to a voltage used as a reference input to the DC-DC converter 800. In some other examples (not shown in FIG. 8), an output of the DAC 802 may be used as feedback to the DC-DC converter 800. In some such examples, the output of the DAC 802 may be added to the local feedback and then input as feedback to the DC-DC converter 800.

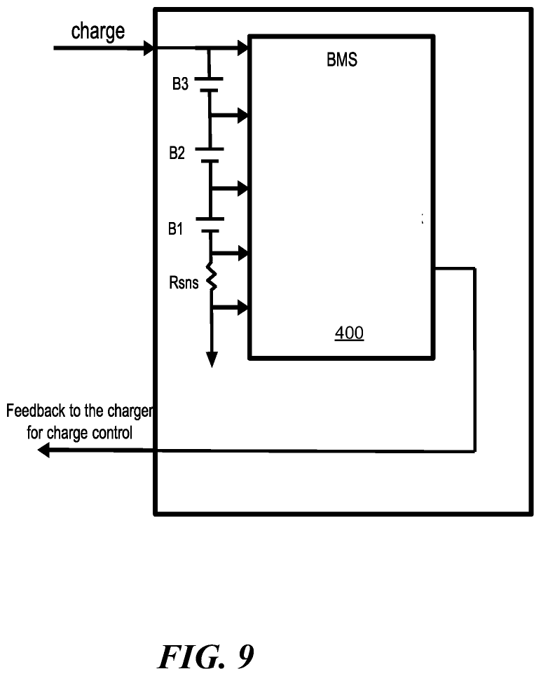

FIG. 9 is a block diagram illustrating another example of a BMS IC 400, in accordance with various aspects of the present disclosure. In the example of FIG. 9, the BMS IC 400 may receive a charge. For example, the charge may be received from a DC-DC converter. Additionally, the feedback may be transmitted to convert a DC-DC converter into an accurate charger. In the example of FIGS. 9, B1, B2, and B3 represent respective batteries in a battery pack, such as a battery pack 404 described with reference to FIGS. 4-8. RSNS is sense resistor used to measure the current.

In one example, the BMS IC, such as the BMS IC 400 described with reference to FIGS. 4-9 may be used in a notebook computer or another portable computing device. A battery pack, such as the battery pack 404 described with reference to FIGS. 4-9, may be stored within the computing device to provide power to the computing device when it is not connected to an external power source. The BMS IC may be located within the battery pack. The BMS IC may be responsible for monitoring and managing the battery pack's operations. A DC-DC converter, such as a DC-DC converter 402, 500, 600, 700, or 800 described with reference to FIGS. 4-8, respectively, may be defined on a motherboard, or other component, of the computing device. The DC-DC converter may provide a charge current to the battery pack. In some examples, the BMS IC may control the output of the DC-DC converter.

Various aspects of the present disclosure are directed to battery management through the introduction of an BMS IC that is strategically positioned in close proximity to the battery. This unique placement grants the BMS IC unparalleled access to telemetry data about the battery, including aspects such as its health, temperature, impedance, and more. Unlike traditional systems that offer limited insights and often necessitate external interventions for adjustments, this BMS IC is equipped to autonomously gather, analyze, and act upon this data. In some examples, the BMS IC may adapt the charging profile based on the ever-evolving conditions of the battery, ensuring optimal charging throughout the battery's lifecycle. In some examples, the BMS IC uses a regulation mechanism that may manipulate the reference voltage and adjust the feedback signal to harnessing the power of both analog and digital communication processes. In some examples, the BMS IC ensures rapid charging by considering a myriad of factors, including available power, manufacturer-specified charge limits, and battery temperature, and dynamically adjusts the charge current based on real-time data. This not only provides swift charging but also ensures the safety and longevity of the battery. Additionally, the BMS IC may balance between system operations and battery charging to ensure uninterrupted functionality.

As discussed, various aspects of the present disclosure are directed to a BMS IC that improves battery charging. In some examples, the BMS IC interfaces directly with a voltage regulator (DC-DC converter), specifically targeting its feedback or reference mechanisms. This interaction enables the BMS IC to exert control over both the output voltage and current. By doing so, what was once a rudimentary voltage regulator undergoes a transformation, effectively becoming a battery charger. With the regulator now functioning as a charger, the BMS IC further refines the charging process. In some examples, the BMS IC actively manipulates the output voltage and current to devise an optimal charging profile. This profile is not static; instead, the charging profile is dynamically tailored to ensure the battery receives a charge that is fast and safe within its operational parameters.

In some examples, the BMS IC is responsible for closing the current loops. This means the BMS IC constantly monitors the flow of current and makes adjustments to ensure it remains within desired limits. Additionally, or alternatively, the BMS IC also closes the voltage loop. By doing so, the BMS IC ensures that the voltage remains precise and consistent, eliminating any potential fluctuations that might harm the battery.

Furthermore, a battery may be composed of individual cells, and each of these cells can have varying voltage levels. In some examples, the BMS IC may adjust the current based on the voltage of each individual cell, ensuring each cell gets the charge it needs. Additionally, just as with voltage, the impedance (or resistance) of individual cells can vary. In some examples, the BMS IC adjusts the charging current based on the impedance of each cell, ensuring efficient and safe charging.

The DC-DC converter is designed to always maintain a predetermined minimum system voltage. This operation occurs autonomously, without any intervention from the BMS IC, ensuring a baseline operational standard. The communication between the BMS and the voltage regulator is novel. For example, the BMS sends a specific frequency to the regulator, which in turn operates a switched-capacitor current mechanism. This mechanism adjusts the reference point for charging. Additionally, this frequency can also be used to make modifications to the feedback node, offering another layer of control over the charging process.

In some examples, the BMS IC is proactive. For example, the BMS IC can measure the system's power usage and adjust the charging current accordingly, ensuring the battery is neither overcharged nor undercharged. Environmental factors, notably temperature, play a significant role in battery health. In some examples, the BMS IC can tweak the charging current based on the overall environmental temperature as well as the temperature of individual cells.

Lastly, in accordance with various aspects of the present disclosure, the BMS IC measures, for example, constantly or periodically measures, the impedance of individual cells. That is, in accordance with various aspects of the present disclosure, the BMS IC has direct control of the charge current. Therefore, the BMS IC may adjust the charge current for the purpose of measuring the impedance of the one or more cells in the battery pack. The impedance depends on various parameters, such as temperature, state of charge (SoC), and/or state of health (SoH). Thus, in accordance with various aspects of the present disclosure the BMS IC, which is aware of the various parameters, can vary the charge current to measure and calculate the impedance of the one or more cells. Based on these readings, the BMS IC, such as the BMS IC 400 described with reference to FIGS. 4-9, can fine-tune the charging current, ensuring optimal battery health and longevity.

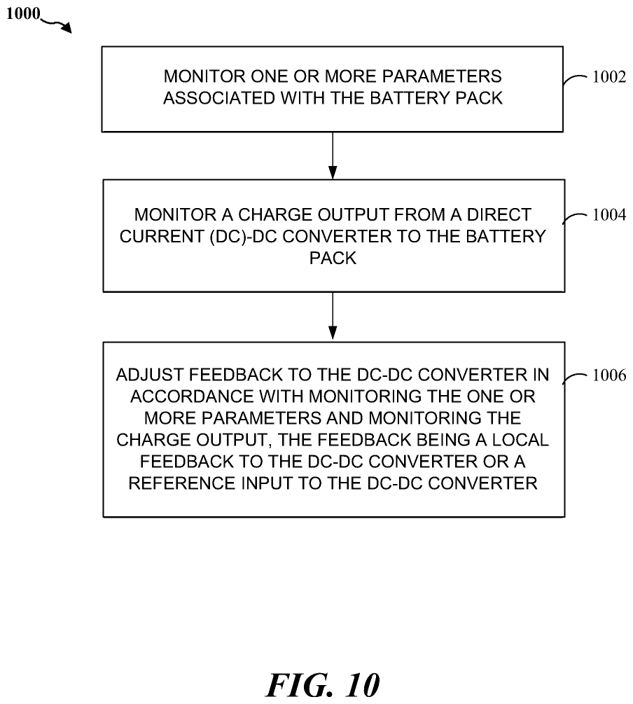

FIG. 10 is a flow diagram illustrating an example process 1000 for controlling an output of a DC-DC converter, in accordance with various aspects of the present disclosure. The example process 1000 may be performed by a BMS IC, such as a BMS IC described with reference to FIG. 4-9. In some examples, the BMS IC is collocated with the battery pack. For example, the BMS IC may be in a same housing as the battery pack or adjacent to a housing of the battery pack. As shown in FIG. 10, the process 1000 begins at block 1002 by monitoring one or more parameters associated with the battery pack. The one or more parameters may include, for example, one or more of a current ambient temperature, one or more temperatures of the battery pack, health or aging status of one or more cells in the battery pack, system power usage, a respective cell voltage level of one or more cells associated with the battery pack, a respective impedance of one or more cells, or a flow of currents entering and/or exiting the battery pack. In some examples, a maximum cell voltage is increased based on identifying an increase in the respective impedance of the one or more cells. In some examples, the process 1000 determines the respective impedance of the one or more cells based on the feedback varying the charge output.

At block 1004, the process 1000 monitors a charge output from a direct current (DC)-DC converter to the battery pack. The DC-DC converter may regulate to a predetermined minimum system voltage without the intervention of the BMS IC. At block 1006, the process 1000 adjusts feedback to the DC-DC converter in accordance with monitoring the one or more parameters and monitoring the charge output, the feedback being a local feedback to the DC-DC converter or a reference input to the DC-DC converter. Adjusting the feedback causes the DC-DC converter to adjust the charge output. The charge output may be a voltage output or a current output. The BMS IC closes a DC-DC current loop and/or a DC-DC voltage loop for charge control. In some examples, an amount of a switched-capacitor current for adjusting the reference input or the local feedback is based on the frequency. The frequency may be a variable. In other examples, the feedback is analog feedback or digital feedback. In some such examples, the digital feedback is converted to an analog signal. Additionally, or alternatively, the feedback may be added with a local feedback signal associated with the charge output of the DC-DC converter.

In some examples, the BMS IC adjusts the feedback based on the respective cell voltage level of the one or more cells satisfying a charge profile condition. For example, the feedback may be used to increase the cell voltage level to a desired level or decrease the cell voltage level to another desired level. Additionally, or alternatively, the BMS IC adjusts the feedback based on identifying an increase in a respective impedance of one or more cells of the battery pack. Additionally, or alternatively, the BMS IC adjusts the feedback based on identifying a respective increase in the one or more temperatures. In such examples, adjusting the feedback reduces the charge output. Each of the one or more temperatures may be measured at a different location in relation to the battery pack.

The foregoing disclosure provides illustration and description, but is not intended to be exhaustive or to limit the aspects to the precise form disclosed. Modifications and variations may be made in light of the above disclosure or may be acquired from practice of the aspects.

As used, the term “component” is intended to be broadly construed as hardware, firmware, and/or a combination of hardware and software. As used, a processor is implemented in hardware, firmware, and/or a combination of hardware and software.

Some aspects are described in connection with thresholds. As used, satisfying a threshold may, depending on the context, refer to a value being greater than the threshold, greater than or equal to the threshold, less than the threshold, less than or equal to the threshold, equal to the threshold, not equal to the threshold, and/or the like.

It will be apparent that systems and/or methods described may be implemented in different forms of hardware, firmware, and/or a combination of hardware and software. The actual specialized control hardware or software code used to implement these systems and/or methods is not limiting of the aspects. Thus, the operation and behavior of the systems and/or methods were described without reference to specific software code—it being understood that software and hardware can be designed to implement the systems and/or methods based, at least in part, on the description.

Even though particular combinations of features are recited in the claims and/or disclosed in the specification, these combinations are not intended to limit the disclosure of various aspects. In fact, many of these features may be combined in ways not specifically recited in the claims and/or disclosed in the specification. Although each dependent claim listed below may directly depend on only one claim, the disclosure of various aspects includes each dependent claim in combination with every other claim in the claim set. A phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (for example, a-a, a-a-a, a-a-b, a-a-c, a-b-b, a-c-c, b-b, b-b-b, b-b-c, c-c, and c-c-c or any other ordering of a, b, and c).

No element, act, or instruction used should be construed as critical or essential unless explicitly described as such. Also, as used, the articles “a” and “an” are intended to include one or more items, and may be used interchangeably with “one or more.” Furthermore, as used, the terms “set” and “group” are intended to include one or more items (for example, related items, unrelated items, a combination of related and unrelated items, and/or the like), and may be used interchangeably with “one or more.” Where only one item is intended, the phrase “only one” or similar language is used. Also, as used, the terms “has,” “have,” “having,” and/or the like are intended to be open-ended terms. Further, the phrase “based on” is intended to mean “based, at least in part, on” unless explicitly stated otherwise.

What is claimed is:

1. A method for controlling a charge to a battery pack via a battery management system (BMS) integrated circuit (IC), comprising:
monitoring one or more parameters associated with the battery pack;
monitoring a charge output from a direct current (DC)-DC converter to the battery pack; and
adjusting feedback to the DC-DC converter in accordance with monitoring the one or more parameters and monitoring the charge output, the feedback being a local feedback to the DC-DC converter or a reference input to the DC-DC converter.

2. The method of claim 1, wherein the BMS IC is collocated with the battery pack.

3. The method of claim 1, wherein the one or more parameters include one or more of a current ambient temperature, one or more temperatures of the battery pack, health or aging status of one or more cells in the battery pack, system power usage, a respective cell voltage level of one or more cells associated with the battery pack, a respective impedance of one or more cells, or a flow of currents entering and/or exiting the battery pack.

4. The method of claim 3, wherein the BMS IC adjusts the feedback based on the respective cell voltage level of the one or more cells satisfying charge profile condition.

5. The method of claim 3, wherein:
the BMS IC adjusts the feedback based on identifying an increase in the one or more temperatures exceeding; and
adjusting the feedback reduces the charge output.

6. The method of claim 3, wherein:
the BMS IC adjusts the feedback based on identifying an increase in the respective impedance of the one or more cells; and
adjusting the feedback reduces the charge output.

7. The method of claim 3, wherein a maximum cell voltage during a charge is increased based on the respective impedance of the one or more cells.

8. The method of claim 3, further comprising determining the respective impedance of the one or more cells based on the feedback varying the charge output.

9. The method of claim 1, wherein the BMS IC closes a DC-DC charge output loop.

10. The method of claim 1, wherein the DC-DC converter regulates to a predetermined minimum system voltage without intervention of the BMS IC.

11. The method of claim 1, wherein:
the feedback is a frequency; and
an amount of a switched-capacitor current for adjusting the reference input or the local feedback is based on the frequency.

12. The method of claim 1, wherein the feedback is analog feedback or digital feedback.

13. The method of claim 12, wherein the digital feedback is converted to an analog signal.

14. The method of claim 1, wherein the feedback is added with a local feedback signal associated with the charge output of the DC-DC converter.

15. The method of claim 1, wherein the charge output includes a current output and a voltage output.

16. The method of claim 1, wherein adjusting the feedback causes the DC-DC converter to adjust the charge output.

17. A charging system, comprising:
a direct current (DC)-DC converter;
a battery pack; and
a battery management system (BMS) integrated circuit (IC), the BMS IC configured to:
monitor one or more parameters associated with the battery pack;
monitoring a charge output from the DC-DC converter to the battery pack; and
adjust feedback to the DC-DC converter in accordance with monitoring the one or more parameters and monitoring the charge output, the feedback being a local feedback to the DC-DC converter or a reference input to the DC-DC converter.

18. The charging system of claim 17, wherein the BMS IC is collocated with the battery pack.

19. The charging system of claim 17, wherein the one or more parameters include one or more of a current ambient temperature, a temperature of the battery pack, health or aging status of one or more cells in the battery pack, system power usage, a respective cell voltage level of one or more cells associated with the battery pack, a respective impedance of one or more cells, or a flow of currents entering and/or exiting the battery pack.

20. The charging system of claim 18, wherein the feedback is analog feedback or digital feedback.
